(19) United States
(12) Patent Application Publication
(10) Pub. No.: US 2025/0087449 A1
(43) Pub. Date: Mar. 13, 2025

(54) Electron Filter

(71) Applicant: Oxford Instruments Nanotechnology Tools Limited, Abingdon (GB)

(72) Inventor: Peter Statham, Abingdon (GB)

(21) Appl. No.: 18/826,469

(22) Filed: Sep. 6, 2024

(30) Foreign Application Priority Data
Sep. 7, 2023 (GB) 2313663.3

(51) Int. Cl. H01J 37/244; H01J 37/05; H01J 37/28

(52) U.S. Cl. CPC H01J 37/244; H01J 37/05; H01J 37/28; H01J 2237/2445; H01J 2237/2448; H01J 2237/24507

(57) ABSTRACT

An X-ray detector adapted to reduce the transmission of backscattered electrons from a specimen therethrough is provided, the X-ray detector comprising: a detection element, and a filter positioned between the specimen and the detection element in use, the filter comprising a first material layer formed from an electrically insulating material and a second material layer formed from an electrically conductive material, the second material layer being arranged on a side of the first material layer closest to the detection element, wherein the X-ray detector is adapted such that the second material layer is electrically connectable, when in use, to a reference potential so as to shield the detection element from an electric field attributable to a build-up of charge in the first material layer due to incident electrons in use.

### CROSS-REFERENCES TO RELATED APPLICATIONS

This application claims the benefits of priority under 35 U.S.C. § 119 to Great Britain Application 2313663.3, filed Sep. 7, 2023, which application is herby incorporated by reference herein in its entirety.

### FIELD OF THE INVENTION

The present invention relates to an X-ray detector and corresponding apparatus and method for reducing a degradation in performance of an X-ray detector due to backscattered electrons and undesirable photons.

### BACKGROUND

Scanning electron microscopes are a type of imaging device that can be used to image a specimen. This is typically performed by scanning the specimen surface with a focused beam of electrons and measuring signals generated by the interaction of electrons with the specimen to construct an image. In some applications, characteristic X-rays are measured using an X-ray detector in order to determine an elemental composition of the specimen.

FIG. 1 provides an exemplary apparatus for X-ray analysis using an electron microscope (EM) 100. An X-ray spectrum is measured by sensing and measuring the energies of individual X-ray photons emitted by a specimen 101 when it is hit by a focused electron beam 102. Each emitted X-ray photon is a particle having an associated energy, and this energy is typically converted into a measurable charge using a solid-state detector 105, said charge being proportional to the energy of the x-ray photon. The charge associated with an incident X-ray photon is then measured so that a count can be recorded, and a histogram of recorded measurements is generated to represent a digitised X-ray energy spectrum. Characteristic peaks of chemical elements can be identified in the X-ray energy spectrum, and the energies at which the peaks are recorded are used as a basis for determining an elemental content of the specimen material 101 under the electron beam 102.

The X-ray detector 105, the final polepiece of the electron microscope 104, and the specimen 101 are usually all located within the same vacuum chamber. The vacuum is primarily needed so that the electrons can be accelerated to several keV energy and focused to a narrow beam without scattering on gas molecules. However, there are alternative configurations where the electron beam may be focused within a vacuum region while the specimen is in a region of higher pressure. The X-ray detector may be located in the same vacuum region as the electron beam or in a region of higher pressure.

Backscattered electrons (BSE) are those electrons from the incident electron beam that are scattered within the specimen and escape the surface travelling in a variety of directions. Consequently, a proportion of the BSEs will strike the X-ray detector 105. Typically, the energy of these BSEs can be as high as those in the incident electron beam. Because these BSEs can cause damage to the X-ray sensor and can interfere with the measurement of the X-ray spectral emissions from the specimen, it is common to provide an electron trap 105a comprising arrangement of magnets at the entrance of the detector to deflect electrons away from the X-ray sensor.

However, if an X-ray detector is positioned below an electron lens in position 106, there is very limited space to insert an electron trap between the specimen and the detector, and the leakage field for any magnets in this vicinity would interfere with the electron optical focusing of the incident electron beam. Therefore, an alternative method of preventing BSEs from reaching the sensor is to insert a filter material between specimen and the detector. WO 2010/115873 is a document describing such an arrangement, where different thicknesses of filter material are used to alter what fraction of BSEs reach the X-ray sensor.

Charging of insulating specimens in the scanning electron microscope and the consequential undesirable influence on imaging performance is a well-known phenomenon (for example see the review “Does Your SEM Really Tell the Truth?—How Would You Know? Part 4: Charging and its Mitigation”, Postek and Vladar 2015 Proc SPIE Int Soc Opt Eng. 2015; 9636: 963605 (Oct. 21, 2015); doi: 10.1117/12.2195344). Similar undesirable effects can occur if any insulating material exposed to backscattered electrons is in the vicinity of the focused electron beam. If the filter material used to absorb BSEs is an insulator, incident BSEs may be slowed down and come to rest within the filter material. As a result, the filter material will acquire negative charge and the magnitude of the electrical potential of the filter material will rise, possibly as far as the magnitude of the voltage used to accelerate the electrons in the incident focused beam. This charging effect of the filter material produces an electrostatic field that can interfere with the scanning electron microscope (SEM) electron optics and cause shift and distortion of images formed by the microscope.

FIG. 2 shows a system comprising an annular X-ray detector beneath an electron lens according to the prior art. Such an arrangement is described in the document DE112015000849T5.

In FIG. 2, an X-ray detector 1 is positioned between the electron beam lens system 42 and the sample table 43 on which a specimen 5 is placed. The focused incident electron beam passes through hole 14 and multiple X-ray sensor elements 11, typically silicon drift detector (SDD) sensors, are arranged around the hole. An X-ray transmission window 12 is provided in front of each sensor. The inside of the X-ray detector module containing the sensors may be evacuated or contain a chosen gas at less than atmospheric pressure. The X-ray transmission window 12 may be formed of a conductive material as beryllium or may be formed of an insulating material such as an insulating polymer. Where the material is an insulating polymer, the transmission window 12 has an electrically conductive material coating on the specimen side of the window that is connected to the electrically conductive window frame 13. The conductive coating is typically aluminium. The detector side of the X-ray transmission window 12 is electrically isolated from the window frame 13 and may be inside the housing of the X-ray sensor.

The X-ray detecting element 11 is electrically connected to the X-ray detection preamplifier 21 as the first stage of pulse processing electronics 22 that are used to measure X-ray photon signals and accumulate an energy histogram representing the X-ray spectrum falling on the sensors 11. The conductive surface of the X-ray transmission window 12 and the window frame 13 are electrically connected to an electron detection preamplifier 23. In addition, a voltage application unit 24 is used to create a positive bias of up to a few hundred volts between the conductive surface and the sample table 43 that is connected to ground potential. X-rays from the specimen pass through the X-ray transmission window 12 to be detected by the sensor 11.

In the configuration described in FIG. 2, if a conductive material such as beryllium is used for the X-ray transmission window, electrons absorbed in the window will flow to the electron-detecting preamplifier, reducing charge build-up in the window. Furthermore, even when an insulating material is used for the X-ray transmission window, the conductive layer on the surface is held at a bias voltage which is positive with respect to ground potential because of the electronic circuitry to measure current. Therefore, the problems of charge accumulation within the insulating material causing electrostatic fields that would affect the image recorded by the SEM are mitigated.

Beryllium is a good choice for an electron filter because it provides good transmission for X-rays while blocking BSEs, is electrically conductive, and X-ray emission from beryllium reaching the X-ray sensor is unlikely to be a problem for most applications of X-ray detectors for material analysis in SEM. However, it is not ideal as beryllium is a hazardous material requiring careful handling. Metals heavier than beryllium could be used for electron filtering, but X-rays generated by electrons striking the filter would be of higher energy and therefore more likely to interfere with the spectral emissions of interest from the specimen.

In addition, although in principle conductive carbon could be used as a filter material, in order to block BSEs up to 20 keV in energy that are typically used in SEM, a four-micron thick layer of carbon would be required. This is not readily available as a self-supporting film.

As a result, polymers with low atomic number constituents such as carbon, nitrogen and oxygen, which can be fabricated as self-supporting films with thicknesses up to several microns, have been the most common choice for both X-ray transmission windows and electron blocking filters. The thicknesses of these films are chosen to provide an optimal trade-off between preventing backscattered electrons from the sample from being transmitted through the film, and allowing X-rays in an energy band useful for elemental analysis to be transmitted through the film. Typically, there are far more BSEs (˜1,000×) emitted from the specimen towards the detector than X-rays, and choosing a filter material and geometry capable of blocking all BSEs would significantly reduce the number of X-rays reaching the sensor, particularly towards the lower end of the useful energy band. As a result, a filter material and geometry are typically chosen to be as transparent as possible to X-rays in an energy band useful for elemental analysis whilst satisfying a condition that the proportion of BSEs which do transmit through the filter do not significantly affect the recorded X-ray spectrum.

However, as described above, when an electrical insulator such as a polymer or Mylar is used as the X-ray transmission window, and the window is used as an electron filter to block transmission of BSEs, charge will still accumulate within the filter due to electrons coming to rest within the filter. Although a conductive coating on the specimen side of the filter material held at a fixed voltage can prevent interference with the operation of the electron optics, charge build-up within the filter can lead to electrostatic breakdown, either within the filter or from the high potential on surfaces to other surfaces in the vicinity or the detector sensor itself. Depending on how close the filter is to the sensor, and what other surfaces are near to the sensor, these breakdown events can give rise to spurious signals on the output of the X-ray sensor and false counts in the recorded energy spectrum.

Another problem with existing implementations of electron filters is that insulating materials such as Mylar may generate optical photons when struck by electrons, an effect called cathodoluminescence. If the filter is close to the X-ray sensor, which is desirable to allow for a large solid angle, these optical photons may transmit through the surface layers of the sensor and, although too low-energy to be detected as individual pulses, will then contribute to the electron current in the sensor which uses up bandwidth, increases the effective noise, and degrades resolution of the recorded spectrum.

Furthermore, when a material layer is used as a filter to block BSE transmission, if there is any gap between the material layer and the sensor and there is an inert gas (e.g. nitrogen, argon, neon, xenon) present at less than atmospheric pressure, or there is some residual gas left on the inside of the X-ray detector module after attempting to evacuate that inside volume, positive ions can be created by collisions of X-ray photons or electrons with gas atoms in the space between the sensor and the electron filter. Since a silicon drift detector (SDD) sensor typically has a negative voltage applied to its entrance surface (the surface through which X-rays enter the SDD to be detected), any positive ions will be accelerated towards this entrance surface. Accumulated gas molecules can influence the performance of the entrance surface of the detector, change trajectories of transmitted BSEs which are attracted towards the more positively charged detector surface, and overall lead to a degradation in spectral resolution for low energy X-rays in particular.

Therefore, in view of the problems above, what is needed is an improved electron filter for BSEs that reduces unwanted side effects which degrade the X-ray detector performance.

### SUMMARY OF INVENTION

In a first aspect of the invention there is provided an X-ray detector adapted to reduce the transmission of backscattered electrons from a specimen therethrough, the X-ray detector comprising: a detection element; and a filter positioned between the specimen and the detection element in use, the filter comprising a first material layer formed from an electrically insulating material and a second material layer formed from an electrically conductive material, the second material layer being arranged on a side of the first material layer closest to the detection element, wherein the X-ray detector is adapted such that the second material layer is electrically connectable, when in use, to a reference potential so as to shield the detection element from an electric field attributable to a build-up of charge in the first material layer due to incident electrons in use.

The inventors have found that by specifically positioning the second material layer on a side of the first material layer facing the detection element of the X-ray detector, the second material layer further acts as an electrostatic shield against electric fields. This acts particularly to reduce so-called “self-counting” effects on the detector resulting from electrostatic discharges and/or electrostatic breakdown, which may be, for example, within the first material layer, from the first material layer to other surfaces in the vicinity of the first material layer, or from the first material layer to the detection element itself. An electrostatic discharge may be observed as a fast transient that causes electromagnetic interference. Such an electrostatic discharge can generate a rapidly changing electric field which can couple onto nearby electrical circuits. In this way, if a discharge occurs when it is positioned in the vicinity the detection element, the resulting changing electric field can momentarily influence the potential distribution and/or induce charge in the detection element. This can produce a step change in the output of the X-ray detector which is erroneously interpreted as an incoming X-ray photon. Therefore, such discharges can give rise to false X-ray counts in the recorded spectrum. The second material layer acts to prevent voltage transients from discharge events caused by charge built up within the first material layer from being sensed by the X-ray detector and thus interfering with the measurements.

The shielding of the detection element may be understood as electrically and/or electromagnetically shielding the detection element. In other words, the second material layer mitigates unwanted effects on the X-ray detector owing to electric fields generated as a result of a build-up of electrons in the first material layer when the detector is in use and electrons are incident upon the first material layer.

The second material layer is adapted such that it is electrically connectable, when in use, to a reference potential. As such, the second material layer is typically electrically connected to a reference potential when in use. The electrical connection is typically a conductive electrical connection. Advantageously, when the second material is electrically connected to a reference potential, for example, to a system ground, in use, shielding of the detection element against unwanted electric fields is provided.

The term “incident electrons” may be understood as electrons generated through interactions between an electron beam and a specimen when the X-ray detector is in use, such as backscattered electrons, which travel along a path between the specimen and the filter such that said electrons irradiate the filter. The second material layer may shield at least a portion of, or preferably the entirety of, the detection element and/or an entrance surface of the detection element.

In some examples, the X-ray detector may be adapted such that the filter is positioned on or in the X-ray detector. Typically, the positioning of the filter may be such that a portion of the second material layer forms an electrical contact with a body suitable for functioning as a current sink when in use, such as a portion of the X-ray detector. For example, the second material layer may form an electrical contact with a portion of the housing of the X-ray detector, which may be conductively connectable to a reference potential, for example, through an electrical connector and/or terminal. In these examples, the portion of the X-ray detector which makes electrical contact with the second material layer may additionally be galvanically isolated from the detection element of the X-ray detector. In some examples, an additional portion of electrically conductive material may be disposed in electrical contact with the second material layer which forms an electrical contact and/or a portion of an electrically conductive pathway for the second material layer.

The second material layer of the filter may also act to reduce a build-up of charge within the first material layer. Specifically, the adaptation of the X-ray detector such that the second material layer is electrically connectable to a reference potential may further be so as to reduce a build-up of charge in the first material layer attributable to incident electrons. When the second material layer is held at a reference potential, typically one of a fixed voltage, reference ground or earth, in addition to the shielding the detection element from problematic electric fields, an electrical path is provided between the second material layer and a current sink, allowing electrons which move from the first material layer into the second material layer to flow through the second material layer and out of the filter. Therefore, the specific arrangement of material layers as described by these implementations of the first aspect mitigate multiple unwanted effects originating from charge build-up in a BSE filter in such a way that these can be prevented from interfering with the recorded X-ray spectrum.

Electrons may get trapped inside the first material layer in localised states and be unable to move freely, but random thermal fluctuations may give an electron enough energy to escape its localised state and move briefly before getting trapped in a new location. Therefore, the movement of electrons through the insulating first material layer is slow, and if electrons impact the first material layer, charge builds up inside the material. However, if a moving electron reaches a conductive surface that can sink current, the electron and thus the charge will escape. Therefore, the presence of the conductive second material layer connected to a reference potential that acts as a current sink will help reduce build-up of charge, particularly in a region of the first material layer that is close to the conductive second material layer. Consequently, electrons that escape out of the first material layer and reach the second material layer will be conducted away from the filter, therefore reducing the charge build-up within the first material layer.

The term “in use” when referring to the X-ray detector will be understood as using the X-ray detector as part of an electron beam apparatus to detect X-rays emitted from a specimen that is being irradiated with a focused beam of electrons.

The X-ray detector may be provided as part of a detector module comprising one or more X-ray detectors, and optionally one or more other types of detectors such as BSE detectors. The term “detector module” may be understood as a reference to the device or set of components being adapted for the purpose of detecting particles, in particular by way of detection elements, in an electron beam apparatus. The detector module may be adapted to be positioned below a polepiece of an electron assembly of an analysis apparatus, and this may be understood as the detector module being suitable for being disposed in such a position in use. In other words, the detector module typically has a size, shape, and detection element configuration that permits the sensors to receive X-rays generated by a specimen in the apparatus in use.

It will be understood that, in the context of this disclosure, the electron beam apparatus or assembly may be thought of as being configured to generate the focused electron beam, and that the detector module may be described as a module for detection of particles. The expression “particles” is used in this disclosure to refer to both electrons and X-ray photons.

Typically, the detector module is adapted to operate while positioned between the polepiece and the specimen, and in particular more proximal to the former than the latter. The detector module is typically also shaped so as to permit passage of the electron beam from the polepiece to the specimen in use. In preferred examples this configuration involves the shape of the detector module defining a space through which the electron beam can pass unimpeded. Typically, the detector module is shaped so as to surround, partly or entirely, that space, and thereby the electron beam in use also. In typical examples, the detector module being positioned below the polepiece may be understood as the detector module being in a position below the polepiece so as to allow the electron beam to pass through to the specimen.

Typically, in examples wherein, in use, a space is defined between the polepiece and the detector module, that space is as small as is practical with the mechanical arrangement to hold the module. The detector module is typically isolated from the specimen chamber environment and may be evacuated, partially evacuated or contain a chosen gas (such as nitrogen, argon or xenon) at less than atmospheric pressure. Alternatively, interface elements may be provided that connect the environment of the X-ray detector to the specimen chamber environment that is maintained by the electron microscope pumping system.

A detection element of the X-ray detector may be considered as an “active” portion of the X-ray detector, which is sensitive to, or outputs a signal in response to, incident X-rays. The output signal may comprise data representative of the detection or energies of received X-ray photons. The detection element may comprise an associated “active area” or “active volume” which will be understood, typically, as the region of the sensor for which the detection element is responsive or sensitive to particles incident on that surface or part thereof. The detection element may, in some examples, comprise a plurality of detection sub-elements, each of which are sensitive to, or configured to output a signal in response to incident X-rays. The detection element or any sub-elements comprise therein may be configured both to detect individual received X-ray photons and to monitor energies of individual received X-ray photons.

Typically, a space or volume is defined between an exterior surface of the filter and a detection element of the X-ray detector. In some examples, said space or volume may be evacuated, partially evacuated or may contain a chosen gas at less than atmospheric pressure.

A material composition of a material layer, in the context of this disclosure, may be understood as said material layer being formed from, either partially or completely, one or more materials. Where an exemplary material or material category, such as a material characterized by its electrical properties, in particular conductivity, is described, the material layer may be entirely, predominantly, or partly formed from said material or material category. Where a material composition includes a metal, this may include an elemental metal or a metal alloy.

The first material layer of the filter is typically formed from a material that is electrically insulating under standard operating conditions of the detector. Standard operating conditions of the detector typically refers to standard temperature and pressure conditions. For example, the first material layer may be formed predominantly from an electrically insulating material.

Suitable materials for the said electrically insulating and conducting materials that are comprised respectively by the first and second material layers may be understood by those skilled in the art according to the normal meaning of these classifications of material. The term “electrically insulating” as used in this disclosure may refer to a material property denoting that electrons cannot flow freely in said material. Functionally, in the context of the disclosure, an electrical insulator used to form the first material layer may be defined as a material that is susceptible to charge build up attributable to incident electrons coming to rest within the material. The term “electrically insulating” may refer to materials which have bound electrons and/or a very small proportion of mobile charge carriers.

Under the band theory of solids, an electrical insulator may be considered a material in which the valence band is separated by a large band gap from the conduction band, thus preventing the free movement of electrons within the material. Examples of electrically insulating materials according to this disclosure may include insulating polymers and polyimides, silicon nitride and silicon dioxide. Electrical insulators may have room temperature resistivities in the order of 10⁸ Ωcm to 10¹⁸ Ωcm. For example, the insulating polymeric material Mylar has a room temperature resistivity of approximately 10¹⁸ Ωcm.

The first material layer is typically further adapted, by way of the material from which it is formed and/or its geometry, to block, partially or completely, transmission of electrons while allowing partial or complete transmission of, or allowing transmission of a comparatively greater proportion of, X-rays having energies within a first range of energies, or a first energy band. The first range may correspond to energies of X-rays that are useful for elemental analysis. This may be a predetermined range of energies. The numerical limits of this range might not necessarily be known. However, preferably the filter is configured to permit at least X-rays in a desired energy band or sub-band thereof. The first band may correspond to a range of X-ray photon energies identified or determined as being useful for analysis. Typically, the material composition or material of the first material layer and/or its thickness along a direction normal to its major surfaces are configured to have the requisite X-ray transparency, and/or requisite opacity to unwanted radiation or particles.

The second material layer of the filter is formed from a material that is electrically conductive under standard operating conditions of the detector at least. For example, the second material layer may be formed predominantly from an electrically conductive material.

The term “electrically conductive” in this disclosure may refer to a material property denoting that electrons can flow freely. Functionally, this may be considered as a material that when connected to a reference potential at a different electrical potential to that of the material, current can flow freely within the material. Thus, when the second material layer, formed from an electrically conductive material, is arranged on the first material layer, electrons which escape out of the first material layer are conducted away through the second material layer such that electrostatic charge accumulation in the material is reduced. The term “electrically conductive” may refer to materials which have free or delocalized electrons and/or a large proportion of mobile charge carriers. Under the band theory of solids, an electrical conductor may be considered a material in which the valence band overlaps with the conduction band, thus allowing the free movement of electrons within the material. Examples of electrically conductive materials according to this disclosure may include metals, certain allotropes of carbon such as graphene, graphite and arrangements of amorphous carbon, and semiconductors such as silicon when highly doped to increase electrical conductivity. Electrical conductors may have room temperature resistivities in the order of 10⁻⁸ Ωcm to 10⁻³ Ωcm. For example, the metals silver, copper, gold and aluminium all have room temperature resistivity values of between 1×10⁻⁶ Ωcm to 3×10⁻⁶ Ωcm. In addition to being formed from an electrically conductive material, the geometry of the first material layer may be adapted such that the first material layer acts as an electrical conductor.

In some examples, the second material layer may be more electrically conductive than the first material layer by at least a factor of 1,000. However, this factor may be larger in other examples. In line with the description of electrical conductors and electrical insulators above, it is to be understood that the second material layer is often many orders of magnitude more electrically conductive than the first material layer. The material of the second material layer may be more electrically conductive than the material of the first material layer by a number of orders of magnitude. This number may be greater than or equal to 9, 14, 15, 20, and 21, for example, and may be less than or equal to 14, 15, 20, 21, and 26, for example.

The resistivities and associated conductivities discussed in this disclosure will be understood as volume resistivities and volume conductivities, or in other words, resistivities and conductivities associated with a bulk of a given material and representative of the ease or difficulty with which an electrical current may flow through a volume of that material.

In some examples, the second material layer may further assist in reducing the transmission of BSEs by being adapted to block, partially or completely, transmission of electrons while allowing partial or complete transmission of X-rays having energies within a first range of energies, or a first energy band. In these examples the material composition or material of the second material layer and/or its thickness are configured in a complementary manner to that of the first material layer such that the overall filter has the requisite X-ray transparency, and requisite opacity to unwanted radiation or particles.

A “reference potential”, in the context of this disclosure, may be understood as an electrical potential which is typically any one of a voltage (usually a fixed or substantially fixed voltage), a reference or system ground, and an earth potential. A reference ground or system ground may refer to a ground reference or zero-volt reference used for the X-ray detector and/or other components of the electron beam assembly in which the X-ray detector is being used. The source of the reference potential is intended to allow current to flow freely in or out of the source while minimising any voltage variation of the source that would affect any other purpose for that reference potential. In other words, the reference potential should have a sufficiently low impedance and/or stability of its electrical potential or voltage so as to act as, and preferably continue to act as in use, a suitable current sink. In some examples, a feedback control mechanism may be provided to improve the voltage stability of the reference potential.

The second material layer being arranged on a side of the first material layer closest to the detection element may be understood as, when a space is provided between the detection element and the filter, an exterior surface of the second material layer is facing towards a surface of the detection element. When no space is provided and the filter is in contact with the detection element, a surface of the second material layer contacts a surface of the detection element. In other words, the second material layer may be thought of as the final material layer through which a particle may travel on a path from the specimen to the detection element.

The first material layer, the second material layer and or any additional material layer of the filter may be provided in the X-ray detector such that they obscure at least a portion of, or all of, the active area of the detection element. Combined with the positioning of the filter between the specimen and the detection element in use, on a path between the specimen and the detection element, BSEs originating from the specimen are incident on the filter before reaching the detection element.

The second material layer may cover partially, or more preferably all of the surface on the side of the first material layer closest to the detection element. A partial or discontinuous covering of the side of the first material layer closest to the detector may include the second material layer comprising one or more continuous portions of the conductive material and/or one or a plurality of holes, preferably apertures, defined by an absence of the conductive material, therebetween. As such, the second material layer may comprise an array and/or grid structure which partially covers the surface on the side of the first material layer closest to the detection element. A partial covering of the side of the first material layer by the second material layer may in some cases have the form of a filamentary net or a grid formed of conductive material. When the geometry of the second material layer comprises one or more discontinuities, either due to a chosen geometry or result of a particular material deposition method, any one or more of the thickness, coverage, and structure of the second material layer may be adapted so as to shield the detection element from an electric field attributable to a build-up of charge in the first material layer due to incident electrons in use. A minimum thickness, when referring to a layer which comprises discontinuities, may refer to a minimum thickness of the one of more continuous portions.

In some examples, the filter may comprise further material layers in addition to a first material layer and a second material layer, and an exemplary arrangement comprising a third material layer is described in further detail below. However, in further examples, the filter may comprise any number of layers to provide the requisite X-ray transparency, requisite opacity to unwanted radiation or particles and requisite mitigation of the problems described relating to charge build-up in the filter.

In some examples, for each additional material layer comprised in the filter that is electrically insulating an adjacent additional material layer that is formed from a material that is electrically conductive is also provided in the filter. In these examples, the filter may comprise a multi-layer structure typically arranged as an alternating pattern of electrically insulating and electrically conductive layers. However, in other examples, different arrangements of electrically conductive and electrically insulating layers may be provided. More generally, the multi-layer structure may form a stack of layers in various arrangements, which may optionally be periodic or repeating or partly so. For instance, a set of two immediately adjacent layers in such a stack may comprise one conductor layer and one insulator layer, and in various embodiments that set may be immediately adjacent, on one or two major surfaces, to a further layer, which may be comprised by a further such set, or may be an isolate layer of its type, or may be a layer of a further or different type or classification. It will be understood that the total thickness of the filter is preferably configured so as to optimise the transparency of the filter to radiation of interest with other requirements. When the filter is made up of multiple material layers, for any material layer that is an electrical insulator, any adjacent layer that is electrically conductive, in electrical contact with the adjacent insulating layer, and connected to reference potential, may assist in reducing the build-up of charge within that insulating layer.

Preferably, the number of material layers having an electrically conductive material composition or being formed form an electrically conductive material is greater than or equal to the number of material layers having an electrically insulating material composition or being formed from an electrically insulating material. As described above, whilst it is required that the final material layer through which a particle may travel on a path from the specimen to the detection element has the properties of the second material layer described herein, the material layer closest to the specimen in use (i.e. the first surface which a particle from the specimen would be incident upon) may be either an electrically insulating layer or electrically conductive layer. However, it is preferable that the material layer furthest from the detection element is electrically conductive and/or blocks undesirable radiation.

Any additional material layer of the filter described as “electrically insulating” may comprise any of the features, structural or functional, of the first material layer described herein. Similarly, any additional material layer described as “electrically conductive” may comprise any of the features, structural or functional, of the second material layer described herein.

Typically, the electric field attributable to a build-up of charge in the first material layer is at least one of a static electric field and a transient electric field. Static electric fields may include, for example, electrostatic fields generated as a result of incident electrons becoming trapped inside the first material layer. Transient electric fields may include those fields generated during electrostatic breakdown or electrostatic discharges, which may be within the first material layer and/or between the first material layer and one or more other surfaces in the vicinity of the detection element.

In some examples, the second material layer is formed from a material or has a material composition comprising at least one of a metal and carbon. As described above, metallic materials and certain allotropes/arrangements of carbon typically possess the required electrical conductivity to conduct electrons out of the filter. Alternatively or additionally, the second material layer is formed from a material or has a material composition comprising a semiconductor such as silicon highly doped to increase its electrical conductivity.

In examples wherein the second material layer is formed from a metal material or has a material composition comprising, typically predominantly, a metal, the metal may comprise at least one of aluminium and titanium. Heavier metals such as chromium, platinum, silver, gold, and copper may also be suitable materials from which the second material layer may be formed, but lighter metals are preferable, since X-rays generated from incident electrons in lighter metals typically have lower energies and thus are less likely to interfere with the spectral emissions of interest from the specimen.

In examples wherein the second material layer is formed from a material or has a material composition comprising carbon, this may be provided in the form of at least one of graphite and amorphous carbon. Due to its conducting nature, graphene may also be a suitable allotrope of carbon for the second material layer.

It has been found that the materials described above, when provided in a suitable geometry, have the requisite electrical conductivity to provide an electrical path and reduce charge build-up in the first material layer. Furthermore, the metallic materials described above, when provided in a suitable geometry, can also assist in reducing light due to cathodoluminescence in the filter from reaching the detector, but still permit the transmission of X-rays having energies that are useful for elemental analysis.

In some examples, the first material layer is formed from a material or has a material composition comprising a polymeric material. In typical examples, the first material layer is formed from at least one of a polyester film derived from polyethylene terephthalate (commonly known by the trade name Mylar), and a polyimide. These materials, when arranged with suitable geometries, generally provide a good trade-off between opacity to electrons and other types of radiation and transparency to X-rays having energies that are useful for elemental analysis. Furthermore, materials of this kind are readily available in the form of self-supporting films at suitable thicknesses normal to their major surfaces for application as BSE filters for SEM applications with typical beam energies. These thicknesses are usually in the order of micrometres.

Preferably, a material of the second material layer is chosen, and/or a geometry, in particular a minimum, or average, in particular mean, thickness of the second material layer is adapted, so as to reduce the transmission therethrough of photons generated from cathodoluminescence of the first material layer. This may be by way of absorption or reflection of photons having wavelengths in the near infrared, visible, or ultraviolet ranges which are typically those ranges in which photons from cathodoluminescence are emitted. The “reduction” in transmission may be with respect to free space or a medium transparent to photons with wavelengths in said ranges, or may be a reduction such that a major proportion of photons are prevented from being transmitted through the layer. The proportion of photons transmitted through the second material layer is dependent on both the material and geometric properties of said layer. In some examples, the second material layer may preclude cathodoluminescent photon transmission by 99%, that is, it may be adapted to reduce by substantially 99% the incidence, on the detector or detector element, of photons generated by cathodoluminescence of the first material layer. However, in other examples, the transmitted proportion may be much less than 1%. In some examples, the second material layer has an average thickness of at least 40 nm, and a 60 nm layer of aluminium has been found to block a sufficient proportion of cathodoluminescence photons.

It has been found by the inventors that typical materials used to form the first material layer and adhesives used to secure the filter to the detector may emit light due to cathodoluminescence caused by electrons striking the said materials. By providing the second material layer facing the detection element and further forming the second material layer from a material adapted to reduce the transmission of cathodoluminescence light therethrough, photons generated through said cathodoluminescence in the filter or any adhesives are prevented from reaching the detection element. A typical arrangement of the second material layer to provide this effect is a layer of aluminium at least 40 nm and preferably at least 60 nm thick.

A “thickness” when referring to any material layer in this disclosure may refer to a thickness in a direction normal to one or more major surfaces of said material layer. Alternatively, a thickness of a material layer may be defined as a shortest possible straight-line path between any two outer surfaces of said material layer. It will be understood that an outer surface may include a surface of the material layer which is in contact with another material layer of the filter.

Typically, the first material layer has an average (mean) thickness in the order of micrometres. However, this may alternatively refer to a maximum or a minimum thickness of the first material layer. It has been found that a first material layer of this thickness typically provides the requisite opacity to electrons and other types of radiation and transparency to X-rays having energies that are useful for elemental analysis. Furthermore, since electrons trapped in the first material layer may only be conducted away from the filter in a region close to the surface of the first material layer in contact with the second material layer, it is advantageous to minimise the thickness of the first material layer, and/or minimise the distance between any part of the first material layer and a surface of the second material layer whilst ensuring that the first material layer prevents the transmission of a significant proportion of BSEs.

In some examples, the first material layer, and/or the filter, is provided as a self-supporting film, which may be understood as the first material layer or filter being capable, in particular, having adequate rigidity or structural integrity, to maintain its shape or substantially so in use, without any additional supporting member or structure that may reduce the performance of the filter in terms of X-ray transmission. In this way, the first material layer may be mounted in the X-ray detector and may be supported only at its edges.

In some examples, the second material layer is arranged as a coating on a surface of the first material layer on the side closest to the detection element. As the second material layer is typically thinner than the first material layer, forming the second material layer as a coating on a surface of the first material layer is a convenient means for providing the second material layer in the filter without requiring the second material layer to be self-supporting. The second material layer may be created as a coating through any material deposition method suitable for the material or materials from which the second material layer is to be formed. The material deposition method may also be chosen such that it is suitable for application onto the materials comprised in the first material layer and/or the entrance surface of the detection element where applicable. For example, the coating may be created through physical vapour deposition (PVD) techniques such as sputtering, evaporation (e.g. electron beam, thermal, or ion assisted), or pulsed laser deposition. Alternatively, chemical vapour deposition (CVD) techniques in different pressure environments, atomic layer deposition, or Plasma-enhanced CVD may be utilized. The deposition technique chosen to create the second material layer may depend on the ability of the first material layer to withstand the conditions under which the deposition takes place and/or the thickness of the layer being created. Using these deposition techniques may allow the second material layer to be created with a thickness in the order of single figure nanometres.

In other examples, the second material layer may be created by modifying a portion of the first material layer to be electrically conductive. In other words, the material or material composition of the first material layer may be modified close to the surface closest to the detector to create an electrically conductive layer.

Typically, the second material layer has an average thickness less than that of the first material layer. Typically, the second material layer has a minimum or average thickness in the order of nanometres or tens of nanometres, and preferably of at least 10 nm. It has been found that this geometry of material layer, when formed from a material or having a suitable material composition, has the requisite electrical conductivity to provide an electrical path so as to reduce charge build-up in the first material layer, and still permits the transmission of X-rays having energies that are useful for elemental analysis. However, if the second material layer is to additionally significantly reduce the incidence, on the detector or detector element, of photons generated by cathodoluminescence in or from the first material layer, the second material layer preferably has an average thickness in the order of tens of nanometres. As described above, in some examples, the second material layer is formed from aluminium and may have an average thickness of at least 40 nm, and preferably at least 60 nm.

Typically, the detection element of the X-ray detector is one of a silicon drift detector (SDD), a PIN diode detector, a gas proportional counter, a charge-coupled device (CCD) array, and a complementary metal-oxide semiconductor (CMOS) array.

Furthermore, it has been found by the inventors that by applying a voltage to the second material layer which is equally negative or more negative than a voltage applied to the entrance surface of the detection element with respect to a system ground, a degradation in performance of the X-ray detector over time may be reduced. This is because a resulting electric field in the region between the filter and detection element will prevent any positive ions in the vicinity from being attracted towards the entrance surface of the X-ray detector. In other words, positive ions will not be attracted towards the detection element, and with an even more negative voltage, said positive ions will be drawn away from the entrance surface.

In some examples, the filter is arranged such that a side of the second material layer closest to the detection element is in contact with an entrance surface of the detection element. The contact may be complete contact (i.e. all of the surface on the side of the second material layer closest to the detection element is in contact with the entrance surface of the detection element) or substantially complete contact. By providing the filter directly onto a surface of the detection element, it is not required that the filter be formed from material layers that are available as self-supporting films, thus allowing different filter materials or material compositions to be used.

Typically, the X-ray detector further comprises a housing, and the filter is arranged so as to cover an opening of the housing. This covering may be a partial covering or a complete (or substantially complete) covering of an opening of the housing. In such examples where the filter is arranged to completely or substantially completely cover the opening, the filter may effectively seal the detector housing. However, this sealing is not essential, and the filter may be provided across an opening in front of the X-ray detector in a position to block BSEs from reaching the detector element.

Preferably, the filter comprises a third material layer, the third material layer being arranged on an opposite side of the first material layer to the second material layer and being formed from an electrically conductive material, wherein the X-ray detector is adapted such that the third material layer is electrically connectable, when in use, to a reference potential.

Advantageously, the third material layer further acts as an additional electrostatic shield which prevents electric fields due to charge build-up in the first material layer from interfering with the electron optics and deflection fields of the scanning electron microscope when in use.

The shielding of the electron optics and deflection fields may be understood as electrically and/or electromagnetically shielding the electron optics and deflection fields. In other words, the third material layer mitigates problematic effects on an electron beam apparatus in use owing to electric fields generated as a result of a build-up of electrons in the first material layer when the detector is in use and electrons are incident upon the first material layer.

The third material layer is adapted such that it is electrically connectable, when in use, to a reference potential. As such, the third material layer is typically electrically connected to a reference potential when in use. This may be in a similar or equivalent manner to the second material layer. The third material layer of the filter may also act to reduce a build-up of charge within the first material layer. Specifically, the adaptation of the X-ray detector such that the third material layer is electrically connectable to a reference potential may further be so as to reduce a build-up of charge in the first material layer attributable to incident electrons, typically in a similar or equivalent manner as described in relation to the second material layer.

In some examples, the X-ray detector may be adapted such that the filter is positioned in the X-ray detector such that a portion of the third material layer forms an electrical contact with a portion of the X-ray detector in the same manner as described above in relation to the second material layer.

When the third material layer is held at a reference potential in use, typically at fixed voltage, reference ground or earth, an additional electrical path to a current sink is provided for electrons to flow through. This electrical path provided by the third material layer is in addition to the electrical path provided by the second material layer. Consequently, electrons that escape out of the first material layer and reach the third material layer will be conducted through the electrical path provided by the third material layer and reference potential away from the filter. In other words, providing both a second material layer and a third material layer as described above further reduces charge build-up in the first material layer due to the plurality of electrical paths through which electrons in the first material layer can escape.

In other words, by requiring that the third material layer is electrically connectable to a reference potential, when connected to such a reference potential when the X-ray detector is in use, some of the electrons which would otherwise be trapped in the first material layer can reach the third material layer, and the electrical path and potential gradient created by the third material layer and reference potential allows those electrons that arrive at the third material layer to be conducted out of the filter. In this way, electrostatic charge build-up inside the first material layer is further reduced during operation of the X-ray detector in an electron beam apparatus.

The third material layer is formed from a material that is electrically conductive under standard operating conditions of the detector. In some examples, the third material layer may be more electrically conductive than the first material layer by at least a factor of 1,000. The third material layer is often many orders of magnitude more electrically conductive than the first material layer. The material of the third material layer may be more electrically conductive than the material of the first material layer by a number of orders of magnitude. This number may be greater than or equal to 9, 14, 15, 20, and 21, for example, and may be less than or equal to 14, 15, 20, 21, and 26, for example.

The third material being provided on an opposite side of the first material layer to the second material layer may be understood as the third material layer being provided on a side of the first material layer closer to specimen when the detector is in use. In examples where only a first material layer, a second material layer and a third material layer are provided in the filter, the third material layer may be thought of as the initial material layer through which a particle may travel on a path from the specimen and to detection element. The third material layer of the filter described herein may comprise any of the features, structural or functional, of the second material layer described herein.

In some examples, the third material layer is formed from a material or has a material composition comprising at least one of a metal and carbon. As described above, metallic materials and certain allotropes/arrangements of carbon typically possess the required electrical conductivity to conduct electrons out of the filter. Alternatively or additionally, the third material layer may be formed form a material or has a material composition comprising a semiconductor such as silicon highly doped to increase its electrical conductivity.

In examples wherein the third material layer is formed from a material or has a material composition comprising a metal, the metal may comprise at least one of aluminium and titanium. As with the second material layer, heavier metals such as chromium, platinum, silver, gold, and copper may also be suitable materials from which the third material layer may be formed, but lighter metals are preferable for the reasons set out earlier in this disclosure.

In examples wherein the third material layer is formed from a material or has a material composition comprising carbon, this may be provided in the form of at least one of graphite and amorphous carbon. Due to its conducting nature, graphene may also be a suitable allotrope of carbon for the third material layer.

Advantageous effects of the materials described above include those described with said materials in relation to the second material layer.

In some examples, the third material layer is arranged as a coating on a surface of the first material layer on the opposite side of the first material layer to the second material layer. The third material layer may be created as a coating through any of the material deposition techniques described above in relation to the second material layer. Advantageous effects include those described with a surface coating in relation to the second material layer.

In other examples, the third material layer may be formed by modifying a portion of the first material layer to change its electrical conductivity, in particular to render it more electrically conductive, so as to render it an electrical conductor. In other words, the material or material composition of the first material layer may be modified close to the surface opposite to the second material layer to create a further electrically conductive layer.

In some examples, the third material layer has an average thickness less than that of the first material layer. Typically, the third material layer has a minimum or average thickness in the order of nanometres or tens of nanometres, and preferably of at least 10 nm. Advantageous effects are the same as those described with a layer thickness in relation to the second material layer. In some examples, the third material layer may have the same or substantially the same average thickness as the second material layer. In other examples, the third material layer has a lower minimum or average thickness than the second material layer.

In a second aspect of the invention, there is provided an apparatus for analysing a specimen, the apparatus comprising: an electron beam assembly for generating a focused electron beam; and an X-ray detector according to the first aspect or any implementation of the first aspect. It will be understood that the advantageous effects set out above in relation to the first aspect equally apply to the second aspect.

The apparatus may further include an accessory device. Such accessory devices may comprise or be an additional X-ray detector fitted with an electron trap supported on a mechanical assembly on which the X-ray detector or detector module is supported also.

In a third aspect of the invention, there is provided a method of analysing a specimen. The method may preferably be performed using an X-ray detector according to examples of the first aspect or an apparatus according to examples of the second aspect. Typically, the method is performed within an electron beam instrument such as electron microscope. The method comprises: using an electron beam assembly to generate a focused electron beam; providing an X-ray detector according to the first aspect or any implementation of the first aspect, wherein the X-ray detector is positioned below a polepiece of the electron beam assembly from which the focused electron beam emerges towards the specimen, such that X-rays and backscattered electrons generated by interactions between the electron beam and the specimen are incident on the filter of the X-ray detector; connecting the second material layer of the filter to a reference potential; and monitoring, using the X-ray detector, energies of individual received X-ray photons. It will be understood that the advantageous effects set out above in relation to the first aspect equally apply to the third aspect.

Specifically, by performing the above method using an X-ray detector according to examples of the first aspect and further connecting the second material layer of the X-ray detector to a reference potential such as a fixed voltage source, reference ground or earth prior to monitoring energies of individual received X-ray photons, an electrical path to a current sink is provided for electrons to flow through the second material layer. As described in relation to the first aspect above, the provision of this electrical path acts to reduce charge build-up due to electrons in the first material layer and shields the detector from electric fields generated as a result of charge build-up inside the first material layer.

The method typically further comprises connecting the second material layer to a fixed voltage source, preferably wherein the voltage applied to the second material layer is equally or more negative than the voltage applied to the entrance surface of the detection element with respect to a system ground.

It has been found by the inventors that by applying a negative voltage to the second material layer equally or more negative than the voltage applied to the entrance surface of the detection element, a degradation in performance of the X-ray detector over time may be reduced. This is because the resulting electric field in the region between the filter will prevent any positive ions in the vicinity from being attracted towards the entrance surface of the X-ray detector. In other words, when the second material layer is held at a negative voltage, at least as negative as the voltage on the front surface of the radiation sensor, then there will be no electric field attracting positive ions towards the surface of the X-ray detector, and with an even more negative voltage, said positive ions will be drawn away from the entrance surface.

In some examples, the X-ray detector is an X-ray detector according to examples of the first aspect which include the third material layer. The advantageous effects of the third material layer described in relation to the first aspect therefore equally apply to the third aspect. In these examples, the method typically further comprises connecting the third material layer to a reference potential. Typically, this comprises connecting the third material layer to a fixed voltage.

Typically, the voltage applied to the third material layer is equal to the voltage applied to the second material layer with respect to a system ground. In this arrangement, a common voltage source may be used to apply a voltage to the second material layer and third material layer.

In a fourth aspect of the invention, there is provided a filter adapted to reduce the transmission of backscattered electrons from a specimen therethrough. The filter is suitable for use in an X-ray detector. The filter comprises: a first material layer formed from an electrically insulating material and a second material layer formed from an electrically conductive material, the second material layer being arranged on a side of the first material layer, and the filter being adapted to be attached to an X-ray detector such that the filter is positioned between the specimen and the detection element in use and the second material layer is arranged on a side of the first material layer closest to a detection element of the X-ray detector. The filter is adapted such that the second material layer is electrically connectable, when in use, to a reference potential so as to shield the detection element from an electric field attributable to a build-up of charge in the first material layer due to incident electrons in use.

The filter may be alternatively or further adapted such that the second material layer is connectable to a reference potential so as to reduce a build-up of charge in the first material layer attributable to incident electrons.

The filter according to the fourth aspect of the invention may comprise any of the features, structural or functional, of the filter described as part of the X-ray detector according to the first aspect of the invention.

### BRIEF DESCRIPTION OF DRAWINGS

Examples of the present invention will now be described, with reference to the accompanying drawings in which:

FIG. 1 shows schematically a first arrangement for X-ray analysis in an electron microscope according to the prior art;

FIG. 2 shows schematically a second arrangement for X-ray analysis in an electron microscope according to the prior art;

FIG. 3 is a schematic cross section of a first example X-ray detector according to the invention;

FIGS. 4A to 4C are schematic cross sections of different filter arrangements for an X-ray detector according to the invention; and

FIG. 5 is a schematic cross section of a second example X-ray detector according to the invention.

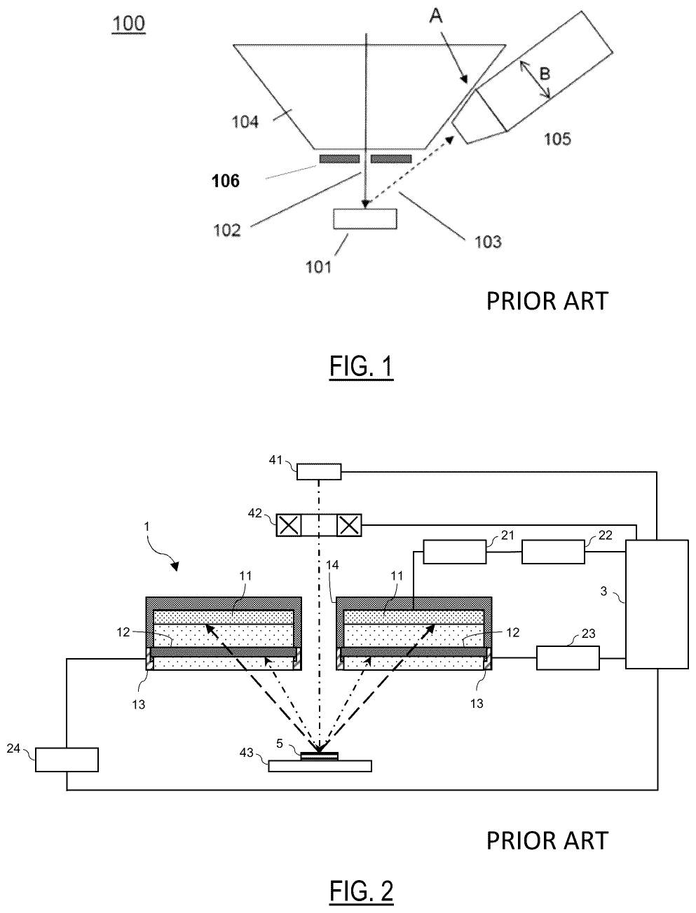

### DETAILED DESCRIPTION

In this document, the convention is that the electron beam travels vertically downwards towards the specimen, and this is the context for words such as “below” and “above”. In practice the electron beam can be oriented in any direction, including vertically upwards. Furthermore, the dimensions of elements shown in the illustrations described herein are not to scale.

FIG. 3 illustrates a first example X-ray detector 300 according to the invention, and in particular shows a cross section through an X-ray detector which is in use with an electron beam assembly. In this embodiment, the detector 300 is located inside a specimen chamber of an electron microscope that is typically evacuated to a low pressure to reduce the scattering of electrons in the focused electron beam by gas molecules.

In FIG. 3, a specimen 301 located on a specimen stage 303 is bombarded by electrons travelling in a focused electron beam 302. At the spot where the focused electron beam 302 strikes the specimen 301, X-ray photons 304 are generated from atoms within the specimen material. Some X-ray photons 304 will travel towards the X-ray detector 300, and any photon passing through an entrance surface 312 of a detection element 311 of the X-ray detector 300 and reaching the active volume will generate a step pulse signal in the accompanying electronics that is proportional to the X-ray energy. The resulting energy histogram of pulse measurements represents the X-ray energy spectrum of emissions from the specimen 301.

A proportion of the electrons incident on the specimen 301 will be scattered back away from the surface as backscattered electrons (BSEs) 305. For X-ray photons 304 and BSEs 305 that travel towards the X-ray detector 300, the X-ray detector 300 is adapted such that these particles must pass through a filter before reaching the detection element 311. The filter is adapted to maximise transmission of X-rays in a useful energy range whilst blocking a proportion of BSEs from reaching the detection element 311.

In the embodiment shown in FIG. 3, the filter comprises a first material layer 306, a second material layer 307, and a third material layer 308. The first material layer 306 if formed from an electrically insulating material, and the second material layer 307 and third material layer 308 are formed from electrically conductive materials. The second material layer 307 and third material layer 308 are arranged on opposite sides of the first material layer 306 such that on a path from the specimen 301 and to detection element 311, an X-ray photon 304 arriving at the detection element 311 passes through the third material layer 308, the first material layer 306 and the second material layer 307 in succession.

The X-ray detector 300 shown in FIG. 3 comprises a detection element 311 that is, in this embodiment, a silicon drift detector (SDD). The detection element 311 has an entrance surface 312 which forms part of an entrance electrode for the detector element 311. This entrance surface 312 is connected to a voltage source 313 that is typically a negative voltage of the order of −100 V. The surface opposite to the entrance electrode in the detection element 311 has many electrodes (not shown) including an electrode that is connected to electronics for measuring pulse signals.

The detection element 311 in FIG. 3 is shown within a detector housing 314 where the inside of the X-ray detector 300 is isolated from the specimen chamber environment and may be evacuated, partially evacuated, or contain a chosen gas (such as nitrogen, argon, or xenon) at less than atmospheric pressure. Alternatively, the detector housing 314 may have interface elements that connect the environment of the X-ray detector 300 to the specimen chamber environment that is maintained by an electron microscope pumping system (not shown). Although FIG. 3 shows the filter effectively sealing the detector housing 314, this is not essential, and the filter just needs to be supported in front of the detection element 311 in a position to block BSEs 305.

To prevent BSEs 305 passing through the filter and being transmitted towards the detection element 312, the first material layer 306 and/or the filter as a whole is provided formed from suitable materials or with a material composition at a sufficient thickness along a direction normal to its major surfaces. In the illustrated embodiment, this direction is vertical on the page. For example, if the energy of electrons within the focused electron beam 302 is approximately 20 keV, a first material layer 306 formed from Mylar or Polyimide at an average thickness of 7 microns is generally sufficient to block a significant proportion of backscattered electrons from reaching the detection element 311. At this average thickness, the first material layer may be provided as a self-supporting film. For some BSEs 305 that travel towards the X-ray detector 300, in the process of being scattered inelastically by atoms in the first material layer 306, they will gradually lose energy, come to rest, and be trapped within said first material layer 306. Since the first material layer 306 is electrically insulating, e.g. comprising polymeric materials such as Mylar or polyimides, in the absence of any electrical path out of the first material layer 306, electrons trapped within the first material layer 306 will cause a build-up of negative charge within the material over time.

In some instances, the build-up of negative charge within the first material layer 306 can lead to electric fields which can interfere with the X-ray detection and/or the electron beam optics, and lead to localised electrostatic breakdown discharge events within the first material layer 306 or to nearby surfaces. These discharge events can produce spurious signals in the X-ray detector electronics that may give rise to artefacts in the recorded X-ray spectrum. To mitigate these effects, the second material layer 307 shown in FIG. 3 is arranged as a coating on a surface of the first material layer 306 on the side closest to the detection element 311. The second material layer 307 is further connected to a voltage source 310 which provides a substantially fixed or fixed voltage to the second material layer 307. Alternatively, the second material layer 307 may be connected to a reference/system ground or earth. In this way, some electrons inside the first material layer 306 can escape towards the second material layer 307, enter the second material layer 307, and be conducted away from the X-ray detector 300, thus reducing the build-up of charge in the first material layer 306. Furthermore, due to its conductivity, the second material layer 307 also acts as an electrostatic shield between the first material layer 306 and the detection element 311 to prevent transient electrostatic discharges from interfering with the X-ray detector 300 and/or its electronics, thus reducing artefacts in the recorded X-ray spectrum.

The second material layer 307 may be arranged on a surface of the first material layer 306 by way of implantation or deposition, and is typically formed from aluminium having an average thickness in the order of tens of nanometres. However, amorphous or crystalline allotropes of carbon or other metals such as chromium, platinum, silver, gold, titanium and copper, could be alternatively used in the material or material composition of the second material layer 307.

Furthermore, when the first material layer 306 is predominantly formed from a material such as Mylar that is cathodoluminescent when exposed to incident electrons, photons generated in the first material layer 306 can be prevented from reaching the detection element 311 by ensuring that the second material layer 307 is of a suitable material and thickness to reflect or absorb said photons. A coating of aluminium (Al) in the order of tens of nanometres in thickness and arranged on the first material layer 306 on the surface closest to the detection element 311 typically blocks a significant proportion of photons generated from cathodoluminescence originating from within the first material layer 306.

In some embodiments, the voltage source 310 may provide a negative voltage to the second material layer 307 that is equally negative or more negative than the voltage applied to the detector entrance surface 312 by voltage source 313 with respect to a system ground. As described above, X-ray photons 304 and/or BSEs 305 travelling towards the detection element 311 may interact with gas molecules in their path, for example in the region 315 in the vicinity of the detector entrance surface 312. This interaction may cause ionisation to occur, leaving behind positive ions. Whereas any positive gas ions in the vicinity of the X-ray detector entrance surface 312 would normally be attracted towards that surface due to its negative bias, when the voltage of voltage source 310 is set equal to or more negative than the voltage of voltage source 313, the resultant electric field would not attract positive ions towards the detection element 311. Preferably, by the application of a more negative voltage by voltage source 310 than voltage source 313, any positive ions will be driven away from the detection element 311. This application of voltage to the second material layer 307 addresses the problem that when positive gas ions are driven towards the detection element 311, unwanted charge can accumulate causing some degradation in performance of the detector, particularly for low energy photons that are absorbed close to the surface.

To further prevent electrostatic fields attributable to the charge build-up in the first material layer 306 from interfering with the electron optics and deflection fields of the scanning electron microscope, the third material layer 308 is arranged as an electrically conductive coating on the side of the first material layer 306 closest to the specimen in use. The third material layer 308 is connected to a voltage source 309, or is alternatively connected to a reference ground or earth. The third material layer 308 provides an additional path to the second material layer 307 for electrons inside the first material layer 306 to escape out of the filter, such that electrons which arrive at the third material layer 308 enter the third material layer 308 and are conducted away. Typically, the voltage source 309 is also connected to the detector housing 314 and may be the same voltage source as voltage source 310. However, the third material layer 309 and detector housing 314 may alternatively be connected to a reference ground or earth.

As with the second material layer 307, the third material layer 308 may be arranged on a surface of the first material layer 306 by way of implantation or deposition. The third material layer is typically also formed from aluminium having an average thickness in the order of tens of nanometres. However, amorphous or crystalline allotropes of carbon or other metals such as chromium, platinum, silver, gold, titanium and copper, could be alternatively used in the material or material composition of the third material layer 308.

Although providing a conductive layer on a side of the first material layer closest to the specimen may assist in reducing interference of the electron beam optics, the third material layer 308 is not essential to reducing the build-up of charge inside the first material layer and/or reducing the proportion of photons generated from cathodoluminescence from reaching the detection element 311.

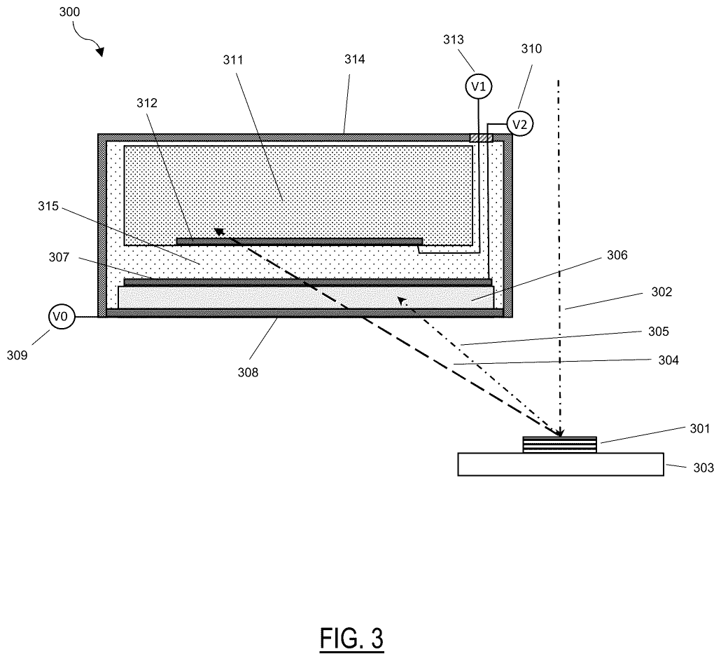

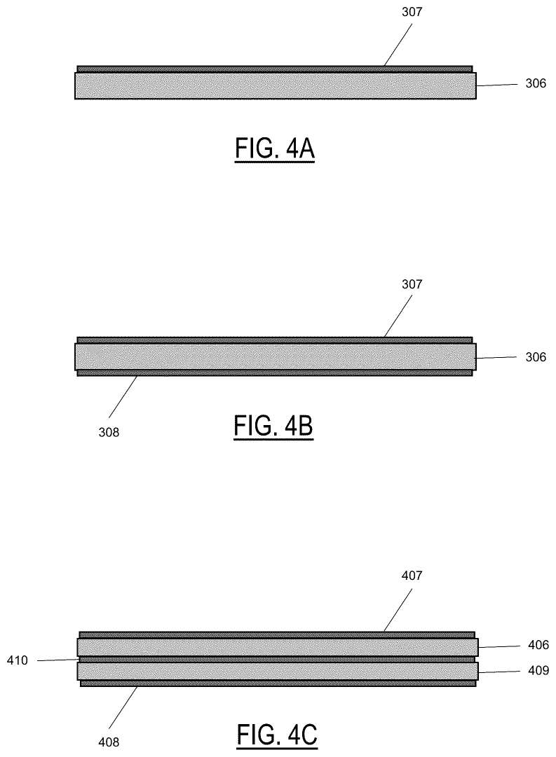

FIGS. 4A to 4C illustrate different implementations of the filter as part of the X-ray detector according to the present invention. In each of these embodiments, the filters are illustrated in an orientation such that X-rays and BSEs generated from a specimen are assumed to approach the filters from below (i.e. the from the bottom of the page).

In FIG. 4A, the filter consists of an electrically insulating layer as a first material layer 306, an electrically conductive layer as a second material layer 307. These material layers comprise the properties of the first material layer 306 and second material layer 307 described previously in relation to FIG. 3. The material layers of the filter are arranged in such a way that incident particles from the specimen must pass through the first material layer 306 and the second material layer 307 in succession to be transmitted through to the detection element 311. In this embodiment, the electrically conductive second material layer 307, when consisting of a suitable material or material composition and geometry, acts simultaneously as an electrostatic shield to prevent discharge events from interfering with the X-ray spectrum, an electrical path for electrons in the first material layer 306 to escape and be conducted away, and a filter to block photons produced by cathodoluminescence in the first material layer 306 and some backscattered electrons 305 from reaching the detection element 311.

FIG. 4B illustrates a filter arrangement additionally comprising a third material layer 308. As described above in relation to FIG. 3, an additional electrically conductive layer located on the specimen side of the first material layer 306, when consisting of a suitable material and geometry, provides a second path for electrons in the first material layer 306 to escape and be conducted away. This additional layer also shields the electron optics of the electron beam from interference due to static electric fields generated by charge in the first material layer 306.

FIG. 4C illustrates a filter comprising an arrangement of electrically conductive and electrically insulating layers formed as a stack of alternating layers. The filter arrangement of FIG. 4C may be thought of conceptually as a combination of the filter arrangements of FIGS. 4A and 4B into a single filter arrangement. In this embodiment, three electrically conductive layers and two electrically insulating layers are provided in an alternating pattern of electrically conductive and electrically insulating layers such that each electrically insulating layer contacts two electrically conductive layers. This alternating arrangement provides multiple electrical pathways for electrons to escape the electrically insulating layers, maximising the reduction in charge build-up inside the two insulating layers when in use. The electrically conductive layer 407 in FIG. 4C comprises equivalent structural and functional features to the second material layer 307 in FIG. 4B. Similarly, the electrically conductive layer 408 in FIG. 4C comprises equivalent structural and functional features to the third material layer 308 in FIG. 4B. The electrically conductive layer 410 is provided as an intermediate conductive layer between the electrically insulating layer 406 and the electrically insulating layer 409. In use, the electrically conductive layer 410 is connected to a fixed voltage source, typically the same as the voltage source the conductive layer 408. Alternatively, both the conductive layer 408 and conductive layer 410 may be connected to a reference/system ground or earth.

In embodiments such as that shown in FIG. 4C where the filter comprises multiple layers of electrically insulating electron filtering material, each layer of insulating material may be thinner than a corresponding layer of insulating material in a filter arrangement that only comprises a single layer of insulating material. This is such that the filter overall provides the sufficient opacity to backscattered electrons and simultaneously sufficient transmission of X-rays having energies suitable for elemental analysis. For example, the electrically insulating layer 406 and electrically insulating layer 409 may perform the same functions and have the same material composition or be formed from the same material as the first material layer 306 in FIG. 4B, but each is typically thinner than the first material layer 306.

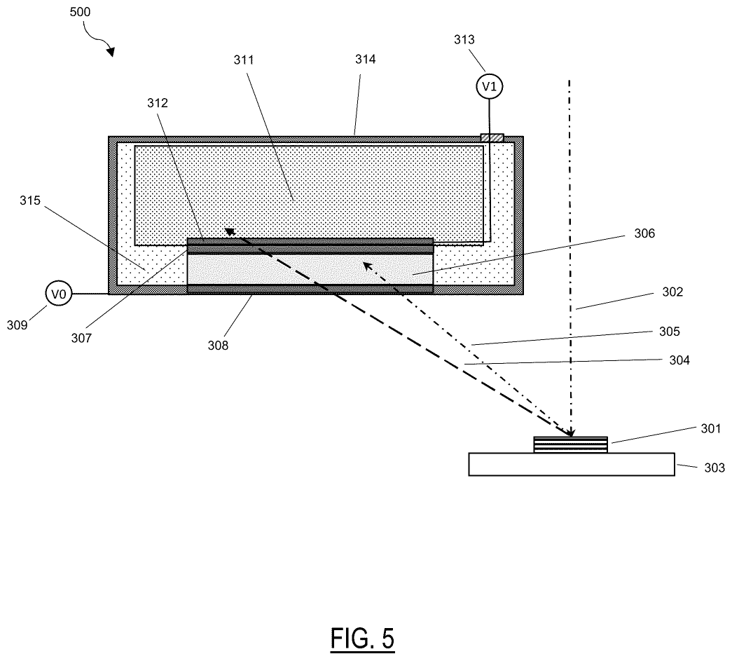

FIG. 5 shows an alternative embodiment of an X-ray detector 500 according to the invention. This embodiment only differs from the embodiment shown in FIG. 3 in that the filter for backscattered electrons is arranged to make direct contact with an entrance surface 312 of the detection element 311, rather than there being a region of space 315 being provided between the filter and the detection element 311. In this embodiment, the side of the second material layer closest to the detection element 311 is in complete contact with the detection surface 312 of the detection element 311, and both are connected to a common voltage source 313, typically providing a negative voltage in the order of −100 V. The layers of the filter are arranged such that the filter comprises a stack of material layers making direct contact with the entrance surface 312. Advantageously, by manufacturing the filter layers directly onto the entrance surface 312 of the detection element 311, it is not required that any of the layers in the filter are available as self-supporting films, thus allowing different filter materials and/or material compositions to be used. Furthermore, as described above in relation to FIG. 3, the third material layer 308 is not essential.

Although the embodiments shown above illustrate an X-ray detector comprising a single element silicon drift detector suitable for use in a scanning electron microscope, the same principle could be used for any X-ray sensor that would be adversely affected by BSEs, electrostatic discharges, cathodoluminescence light, or a build-up of positive gas ions. Thus, the filter arrangement described may be used with a PIN diode semiconductor detector or a gas proportional counter or a CCD imaging array or a CMOS imaging array for example.

1. An X-ray detector adapted to reduce the transmission of backscattered electrons from a specimen therethrough, the X-ray detector comprising:
a detection element; and
a filter positioned between the specimen and the detection element in use, the filter comprising a first material layer formed from an electrically insulating material and a second material layer formed from an electrically conductive material, the second material layer being arranged on a side of the first material layer closest to the detection element,
wherein the X-ray detector is adapted such that the second material layer is electrically connectable, when in use, to a reference potential so as to shield the detection element from an electric field attributable to a build-up of charge in the first material layer due to incident electrons in use.

2. The X-ray detector according to claim 1, wherein the electric field attributable to a build-up of charge in the first material layer is at least one of a static electric field and a transient electric field.

3. The X-ray detector according to claim 1, wherein the second material layer is formed from a material comprising at least one of a metal and carbon.

4. The X-ray detector according to claim 3, wherein the second material layer is formed from a material comprising a metal, and the metal comprises at least one of aluminium and titanium.

5. The X-ray detector according to claim 3, wherein the second material layer is formed from a material comprising carbon in the form of at least one of graphite and amorphous carbon.

6. The X-ray detector according to claim 1, wherein the first material layer is formed from a material comprising a polymeric material.

7. The X-ray detector according to claim 1, wherein at least one of: a material of the second material layer is chosen, and a geometry of the second material layer adapted, so as to reduce the transmission therethrough of photons generated from cathodoluminescence of the first material layer.

8. The X-ray detector according to claim 1, wherein the first material layer is provided as a self-supporting film.

9. The X-ray detector according to claim 1, wherein the second material layer is arranged as a coating on a surface of the first material layer on the side closest to the detection element.

10. The X-ray detector according to claim 1, wherein the second material layer has an average thickness less than that of the first material layer.

11. The X-ray detector according to claim 1, wherein the detection element is one of a silicon drift detector, a PIN diode detector, a gas proportional counter, a CCD array, and a CMOS array.

12. The X-ray detector according to claim 1, wherein the filter is arranged such that a side of the second material layer closest to the detection element is in contact with an entrance surface of the detection element.

13. The X-ray detector according to claim 1, wherein the X-ray detector further comprises a housing, and wherein the filter is arranged so as to cover an opening of the housing.

14. The X-ray detector according to claim 1, wherein the filter comprises a third material layer, the third material layer arranged on an opposite side of the first material layer to the second material layer and being formed from an electrically conductive material, wherein the X-ray detector is adapted such that the third material layer is electrically connectable, when in use, to a reference potential.

15. The X-ray detector according to claim 14, wherein the third material layer is formed from a material comprising at least one of a metal and carbon.

16. The X-ray detector according to claim 15, wherein the third material layer is formed from a material comprising a metal, and the metal comprises at least one of aluminium and titanium.

17. The X-ray detector according to claim 15, wherein the third material layer is formed from a material comprising carbon in the form of at least one of graphite and amorphous carbon.

18. The X-ray detector according to claim 14, wherein the third material layer is arranged as a coating on a surface of the first material layer on the opposite side of the first material layer to the second material layer.

19. The X-ray detector according to claim 14, wherein the third material layer has an average thickness less than that of the first material layer.

20. An apparatus for analysing a specimen, the apparatus comprising:
an electron beam assembly for generating a focused electron beam; and
an X-ray detector according to claim 1.

21. A method of analysing a specimen, the method comprising:
using an electron beam assembly to generate a focused electron beam;
providing an X-ray detector according to claim 1, wherein the X-ray detector is positioned below a polepiece of the electron beam assembly from which the focused electron beam emerges towards the specimen, such that X-rays and backscattered electrons generated by interactions between the electron beam and the specimen are incident on the filter of the X-ray detector;
connecting the second material layer of the filter to a reference potential; and
monitoring, using the X-ray detector, energies of individual received X-ray photons.

22. The method according to claim 21, comprising connecting the second material layer to a fixed voltage source, preferably wherein the voltage applied to the second material layer is equally or more negative than a voltage applied to the entrance surface of the detection element with respect to a system ground.

23. The method according to claim 21, wherein the filter comprises a third material layer, the third material layer arranged on an opposite side of the first material layer to the second material layer and being formed from an electrically conductive material, wherein the X-ray detector is adapted such that the third material layer is electrically connectable, when in use, to a reference potential, and wherein the method further comprises connecting the third material layer to a reference potential.

24. The method according to claim 23, comprising connecting the third material layer to a fixed voltage.

25. The method according to claim 23, wherein the voltage applied to the third material layer is equal to the voltage applied to the second material layer with respect to a system ground.
